(19) United States
(12) Patent Application Publication
(10) Pub. No.: US 2022/0291581 A1
(43) Pub. Date: Sep. 15, 2022

(54) TEMPLATE AND MANUFACTURING METHOD THEREOF

(71) Applicant: Kioxia Corporation, Tokyo (JP)

(72) Inventors: Takeharu MOTOKAWA, Zushi Kanagawa (JP); Noriko SAKURAI, Yokohama Kanagawa (JP); Hideaki SAKURAI, Kawasaki Kanagawa (JP)

(73) Assignee: Kioxia Corporation, Tokyo (JP)

(21) Appl. No.: 17/447,044

(22) Filed: Sep. 7, 2021

(30) Foreign Application Priority Data
Mar. 12, 2021 (JP) 2021-040738

(51) Int. Cl. G03F 7/00

(52) U.S. Cl. CPC G03F 7/0002; B82Y 40/00

(57) ABSTRACT

A template according to an embodiment includes a substrate and a first layer. The substrate includes a first face having a pattern, and contains a first element. The first layer is in contact with the first face, and contains a compound having the first element and a second element different from the first element, the density of the compound in the first layer being higher than the density of the compound in the substrate.

### CROSS REFERENCE TO RELATED APPLICATIONS

This application is based upon and claims the benefit of priority from the prior Japanese Patent Application No. 2021-040738, filed on Mar. 12, 2021, the entire contents of which are incorporated herein by reference.

### FIELD

The embodiments of the present invention relate to a template and a manufacturing method thereof.

### BACKGROUND

In nanoimprinting that can form a fine pattern in a semiconductor device, a template having a uneven pattern region is pressed against resist that has been applied to a film to be processed. Accordingly, the uneven pattern is transferred to the resist. However, pattern roughness on the template is also transferred as it is.

### BRIEF DESCRIPTION OF THE DRAWINGS

FIG. 1 is a cross-sectional view illustrating an exemplary configuration of a template according to a first embodiment;

FIG. 2 is a plan view illustrating an exemplary configuration of the template according to the first embodiment;

FIG. 3A is a cross-sectional view illustrating an exemplary method of manufacturing the template according to the first embodiment;

FIG. 3B is a cross-sectional view illustrating an exemplary method of manufacturing the template, continued from FIG. 3A;

FIG. 4A is a cross-sectional view illustrating an exemplary method of manufacturing the template according to the first embodiment;

FIG. 4B is a cross-sectional view illustrating an exemplary method of manufacturing the template, continued from FIG. 4A;

FIG. 4C is a cross-sectional view illustrating an exemplary method of manufacturing the template, continued from FIG. 4B;

FIG. 5A is a cross-sectional view illustrating an exemplary method of manufacturing a template according to a second embodiment;

FIG. 5B is a cross-sectional view illustrating an exemplary method of manufacturing the template, continued from FIG. 5A;

FIG. 5C is a cross-sectional view illustrating an exemplary method of manufacturing the template, continued from FIG. 5B;

FIG. 5D is a cross-sectional view illustrating an exemplary method of manufacturing the template, continued from FIG. 5C;

FIG. 5E is a cross-sectional view illustrating an exemplary method of manufacturing the template, continued from FIG. 5D;

FIG. 5F is a cross-sectional view illustrating an exemplary method of manufacturing the template, continued from FIG. 5E;

FIG. 6 is a cross-sectional view illustrating an exemplary method of manufacturing a template according to a third embodiment;

FIG. 7 is a cross-sectional view illustrating an exemplary method of manufacturing a template according to a fourth embodiment;

FIG. 8A is a cross-sectional view illustrating an exemplary method of manufacturing a template according to a fifth embodiment;

FIG. 8B is a cross-sectional view illustrating an exemplary method of manufacturing the template, continued from FIG. 8A;

and

FIG. 9 is a cross-sectional view illustrating an exemplary method of manufacturing a template according to Comparative Example.

### DETAILED DESCRIPTION

Embodiments will now be explained with reference to the accompanying drawings. The present invention is not limited to the embodiments. In the present specification and the drawings, elements identical to those described in the foregoing drawings are denoted by like reference characters and detailed explanations thereof are omitted as appropriate.

A template according to the present embodiment includes a substrate and a first layer. The substrate includes a first face having a pattern, and contains a first element. The first layer is in contact with the first face, and contains a compound having the first element and a second element different from the first element, the density of the compound in the first layer being higher than the density of the compound in the substrate.

### First Embodiment

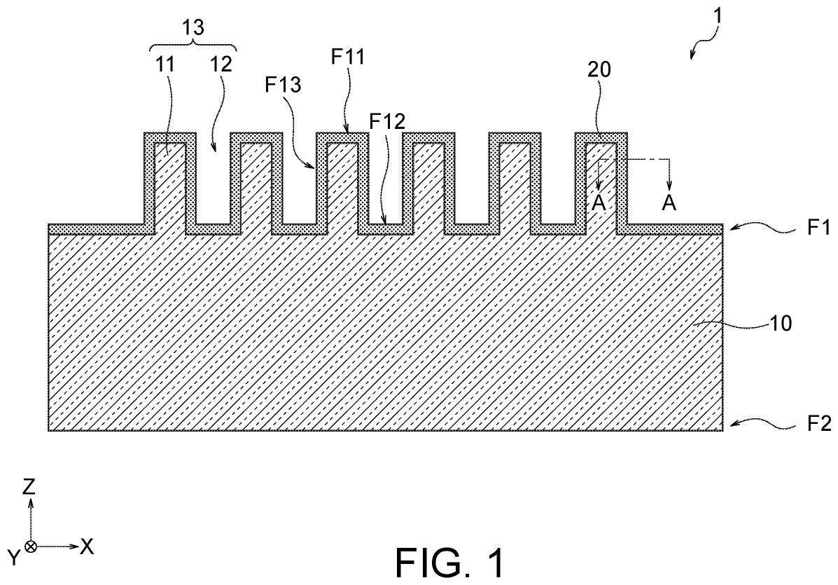

FIG. 1 is a cross-sectional view illustrating an exemplary configuration of a template 1 according to a first embodiment. The template 1 is a template for nanoimprinting, for example.

The template 1 includes a substrate 10 and a compound-containing layer 20.

The substrate 10 includes a face F1 and a face F2 on the side opposite to the face F1. The face F1 of the substrate 10 is provided with an uneven pattern 13. In nanoimprinting, the template 1 is pressed against resist that has been applied to a film to be processed, so that the uneven pattern 13 is transferred to the resist.

The uneven pattern 13 includes protrude patterns 11 and recess patterns 12. Upper face portions of the protrude patterns 11 correspond to an upper face F11. Bottom face portions of the recess patterns 12 correspond to a bottom face F12. Sidewall portions of the protrude patterns 11 correspond to side faces F13. It should be noted that the +Z-direction, which is a direction in which the protrude patterns 11 protrude, is assumed as the upward direction, and the −Z-direction, which is a direction in which the recess patterns 12 are recessed, is assumed as the downward direction.

The substrate 10 is a quartz glass substrate, for example. Thus, the substrate 10 contains silicon dioxide (SiO₂). In addition, the substrate 10 also contains a first element. In such a case, the first element is silicon (Si), for example.

The compound-containing layer 20 is provided on the face F1 along at least the uneven pattern 13. The compound-containing layer 20 is provided on the surface layer of the uneven pattern 13 so as to be exposed from the substrate 10. As described below, the compound-containing layer 20 can reduce roughness of the uneven pattern 13.

The compound-containing layer 20 contains a compound having the first element and a second element different from the first element, and the density of the compound in the compound-containing layer is higher than that in the substrate 10. The second element is an element not contained as a main material of the substrate 10. For example, the second element is carbon (C). The compound of the compound-containing layer 20 is a silicon compound, such as silicon carbide (SiC) or silicon oxycarbide (SiOC), for example. More specifically, the compound-containing layer 20 is a mixed layer of a compound and a material of the substrate 10. That is, the surface layer of the face F1 of the substrate 10 contains a mixture of silicon carbide and silicon dioxide. It should be noted that the compound-containing layer 20 may be a single layer of a compound.

Described below is an example in which the material of the substrate 10 is quartz, the first element is silicon, the second element is carbon, and the compound of the compound-containing layer 20 is silicon carbide.

Silicon carbide in the compound-containing layer 20 can be identified by confirming its electronic state using X-ray photoelectron spectroscopy, for example. The density of the compound-containing layer 20 can be measured using X-ray reflectivity (XRR), for example. The density of silicon carbide is about 3.21 g/cm³, for example. The density of quartz is about 2.21 g/cm³, for example. In addition, the density of the mixed layer is about 2.25 g/cm³, for example.

The compound-containing layer 20 may contain carbon ions and silicon dioxide. This is because not all of the carbon ions necessarily react with silicon in the substrate 10. Thus, the density of carbon ions in the compound-containing layer 20 may be higher than that in the substrate 10.

The compound-containing layer 20 is an ultrathin film. The thickness of the compound-containing layer 20 is less than or equal to 3 nm, for example.

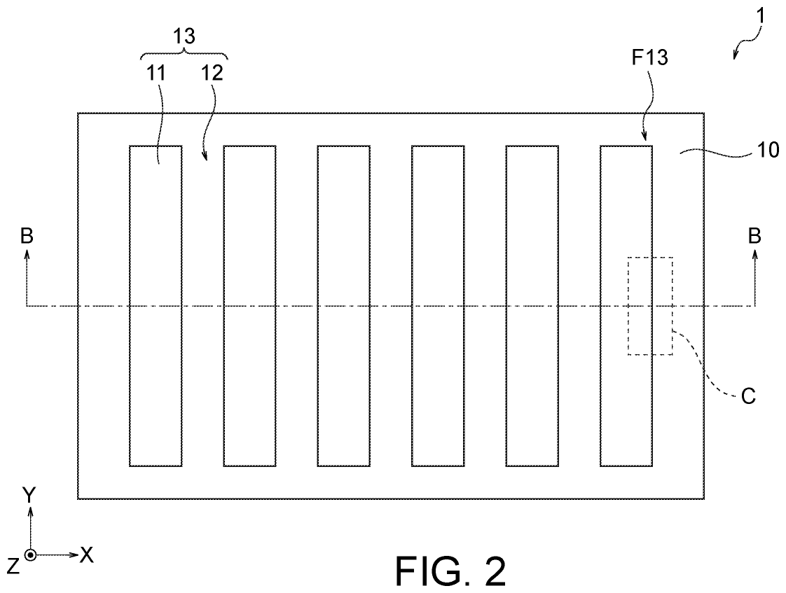

FIG. 2 is a plan view illustrating an exemplary configuration of the template 1 according to the first embodiment. Line B-B in FIG. 2 illustrates a cross-section corresponding to FIG. 1 that is the cross-sectional view.

In the example illustrated in FIG. 2, the uneven pattern 13 is a line-and-space pattern. The protrude patterns 11 extend in the Y-direction. The plurality of protrude patterns 11 are arranged side by side in the X-direction. Each recess pattern 12 corresponds to a gap between two protrude patterns 11. The roughness of the uneven pattern 13 is line edge roughness, for example.

Next, a method of manufacturing the template 1 will be described.

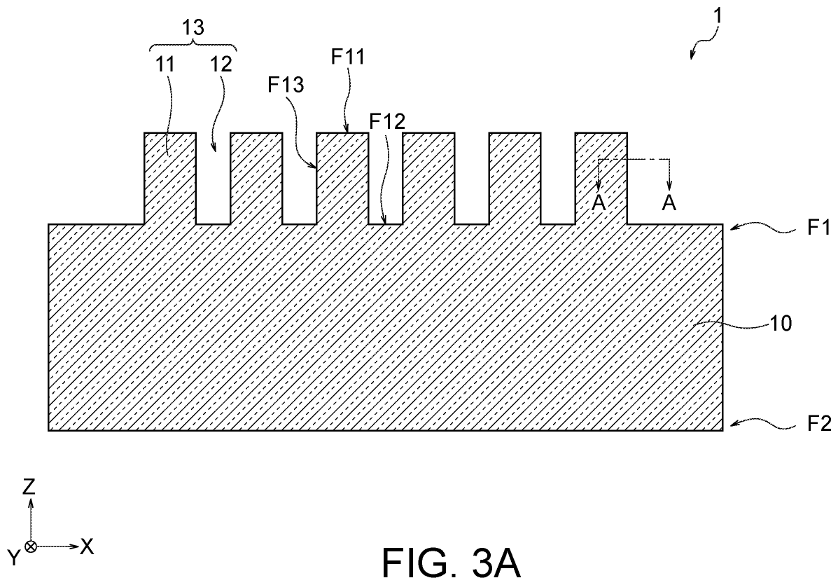

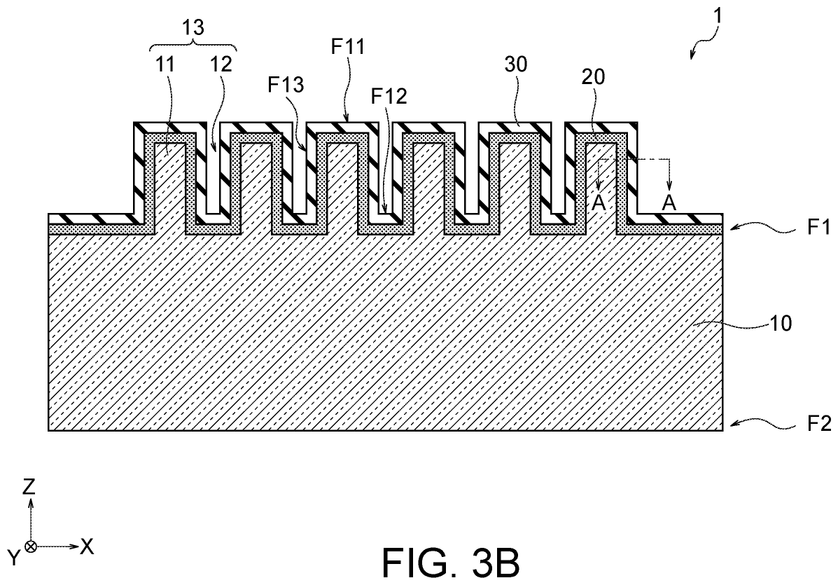

FIGS. 3A and 3B are cross-sectional views illustrating an exemplary method of manufacturing the template 1 according to the first embodiment.

First, as illustrated in FIG. 3A, the uneven pattern 13 is formed on the substrate 10. For example, a mask is formed on the surface of the plate-like substrate 10. The mask is a chromium mask, for example, and has been patterned into a desired shape. After that, portions of the substrate 10 not covered with the mask are removed with fluorine-based plasma, so that the uneven pattern 13 is formed.

Next, as illustrated in FIG. 3B, carbon ions are implanted into at least the uneven pattern 13, so that the compound-containing layer 20 is formed. More specifically, carbon ions are implanted, and also, a material film 30 containing carbon ions is formed so as to cover at least the uneven pattern 13, so that the compound-containing layer 20 is formed between the substrate 10 and the material film 30. The material film 30 is a carbon film, such as a DLC (diamond-like carbon) film, for example.

The material film 30 is formed by plasma-based ion implantation and deposition (PBII&D), for example. In PBII&D, ion implantation and deposition of the material film 30 are performed. In PBII&D, an ion energy of about 100 V is added per carbon ion, for example, depending on a reactant gas used for deposition. The ion energy influences the intensity of ion implantation. As the accelerating voltage is higher, higher ion energy is added, and thus, carbon ions enter the substrate 10 more deeply. Examples of the reactant gas used for deposition include methane (CH₄), acetylene (C₂H₂), and toluene (CH_{B}).

When carbon ions are ion-implanted into the substrate 10, Si—O bonds in silicon dioxide of quartz are broken, and then, silicon and carbon are combined to form silicon carbide. In this manner, the compound-containing layer 20 is formed on the outermost layer of the substrate 10. The compound-containing layer 20 is formed substantially at the same time as the material film 30 is formed, for example.

It should be noted that the method of forming the compound-containing layer 20 and the material film 30 is not limited to PBII&D, and other methods may also be used. For example, to efficiently form the compound-containing layer 20, it is also possible to use other methods that allow active species present during deposition of the material film 30 to be ion-implanted into the surface layer of the substrate 10. Alternatively, it is also possible to use other methods of forming the compound-containing layer 20 without forming the material film 30.

After the step in FIG. 3B, the material film 30 is removed so as to expose the compound-containing layer 20. Removing the entire material film 30 can complete the template 1 illustrated in FIG. 1. The material film 30 is removed by etching using oxygen plasma, for example. When exposed to oxygen plasma, the material film 30, which is a carbon film, is oxidized into a gas of carbon dioxide (CO₂), for example, and thus is removed. It should be noted that silicon carbide and silicon dioxide are not removed with oxygen plasma. Thus, the compound-containing layer 20 and the substrate 10 remain without being removed almost at all.

Next, roughness will be described along a manufacturing flow.

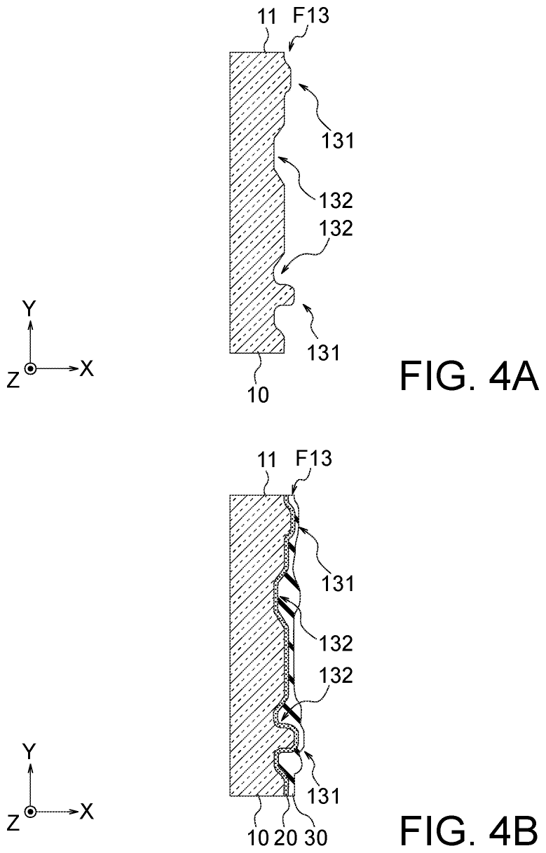

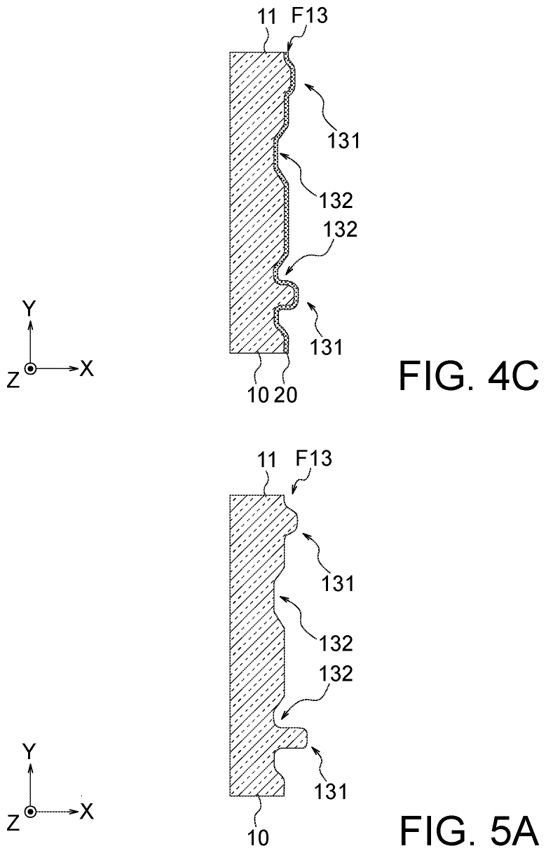

FIGS. 4A to 4C are cross-sectional views illustrating an exemplary method of manufacturing the template 1 according to the first embodiment. FIGS. 4A to 4C are cross-sectional views of the protrude pattern 11 as seen from a cross-section along line A-A in FIGS. 3A, 3B, and 1. In addition, FIGS. 4A to 4C are cross-sectional views around the side face F13 of the protrude pattern 11 when a region in a dashed frame C in FIG. 2 is seen in the Z-direction. Thus, FIGS. 4A to 4C illustrate line edge roughness.

First, as illustrated in FIG. 4A, the uneven pattern 13 is formed on the substrate 10. The side face F13 of the protrude pattern 11 has roughness. Roughness refers to minute protrusions and recesses. The side face F13 has roughness protrusions 131 that protrude from the side face F13, and roughness recesses 132 that are recessed from the side face F13. The amplitude of the roughness protrusions 131 and the roughness recesses 132 is about 1 nm to about 2 nm, for example. For example, roughness is larger as the difference between the upper faces of the roughness protrusions 131 and the bottom faces of the roughness recesses 132 is greater. It should be noted that the +X-direction that is a direction in which the roughness protrusions 131 protrude is assumed as the upward direction, and the −X-direction that is a direction in which the roughness recesses 132 are recessed is assumed as the downward direction.

The upper face F11, the bottom face F12, and the side face F13 of the uneven pattern 13 are ideally flat. However, in practice, as the upper face F11, the bottom face F12, and the side face F13 are magnified, minute protrusions and recesses (i.e., roughness) are also magnified to a nonnegligible level. Roughness can be measured down to the atomic size, for example. The amplitude of the roughness protrusions 131 and the roughness recesses 132 is less than or equal to 10% to 20% of the amplitude of the uneven pattern 13, for example. The smaller the uneven pattern 13, the more difficult it is to reduce roughness relative to the uneven pattern 13. Nanoimprinting has high transfer performance. Thus, the uneven pattern 13 of the template 1 is transferred as it is. Therefore, there is a possibility that the roughness of the uneven pattern 13 may also be transferred as it is. Thus, the template 1 with roughness less than or equal to a predetermined tolerance is typically used in nanoimprinting.

Next, as illustrated in FIG. 4B, the compound-containing layer 20 and the material film 30 are formed.

Next, as illustrated in FIG. 4C, the material film 30 is entirely removed so as to expose the compound-containing layer 20. This improves the line edge roughness by about 15%, for example. This is because the roughness protrusions 131 of quartz are removed through the series of processes.

As described above, according to the first embodiment, the compound-containing layer 20 is provided so as to be exposed on the surface layer of the substrate 10 along the uneven pattern 13. Accordingly, roughness can be reduced.

The compound-containing layer 20 is a film containing silicon carbide (SiC) as described above. Silicon carbide has characteristics intermediate between those of silicon (Si) and diamond (C), and has excellent hardness. As an index of scratch resistance, the modified Mohs scale is used. The modified Mohs scale of quartz is 8, and the modified Mohs scale of silicon carbide is 13. Thus, silicon carbide of the compound-containing layer 20 has higher scratch resistance than quartz of the substrate 10. Silicon carbide in the surface layer of the uneven pattern 13 serves as a hard film coat. This can suppress defects, such as scratches on the uneven pattern 13, which would deteriorate the quality of the transferred pattern.

As another method of forming a silicon carbide film, thermal CVD (chemical vapor deposition) using a source gas containing Si and C may be used, for example. The process temperature of thermal CVD is typically as high as about 2000° C. The temperature is higher than the process temperature (for example, about 1900° C.) of quartz. Thus, it is difficult to deposit silicon carbide on the uneven pattern of quartz with high accuracy using thermal CVD.

In contrast, in the first embodiment, the material film 30 is deposited on the uneven pattern 13 of quartz at room temperature using PBII&D, and also, a silicon carbide film is formed. Accordingly, the uneven pattern 13 of quartz covered with an ultrathin silicon carbide film can be manufactured without through a high-temperature process.

It should be noted that the material of the substrate 10 is not limited to quartz and may be other materials. The compound of the compound-containing layer 20 is not limited to silicon carbide and may be other compounds.

A first protrude portion as the roughness protrusions 131 may be interpreted as at least one of the roughness protrusions 131. A first recess portion as the roughness recesses 132 may be interpreted as at least one of the roughness recesses 132.

### Second Embodiment

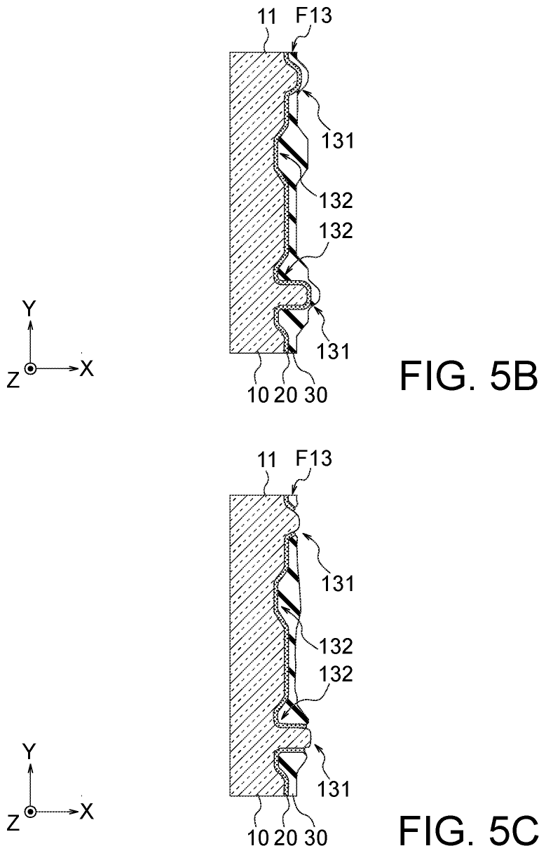

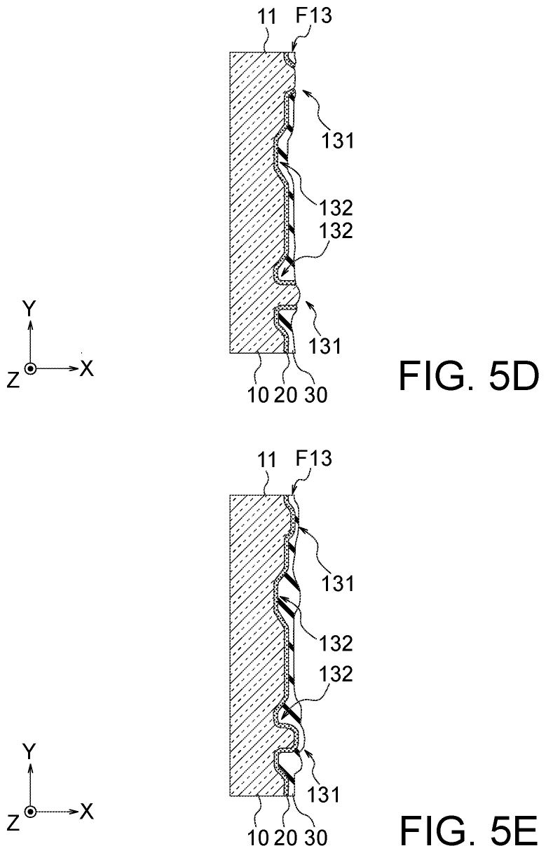

FIGS. 5A to 5F are cross-sectional views illustrating an exemplary method of manufacturing the template 1 according to a second embodiment. The second embodiment differs from the first embodiment in that the step of depositing and removing the material film 30 is performed more than once.

First, as illustrated in FIG. 5A, the uneven pattern 13 is formed on the substrate 10. The step in FIG. 5A is substantially similar to the step in FIG. 4A of the first embodiment.

Next, as illustrated in FIG. 5B, carbon ions are implanted into the uneven pattern 13, and also, the material film 30 is formed so as to cover the uneven pattern 13. More specifically, the material film 30 is formed such that its deposition rate on the roughness protrusions 131 is lower than its deposition rate on the roughness recesses 132. For example, when a carbon film is deposited using PBII&D, a carbon material tends to deposit faster on the roughness recesses 132 than on the roughness protrusions 131, that is, the deposition rate on the roughness recesses 132 tends to be higher than that on the roughness protrusions 131. That is, in the early stage of deposition, the material film 30 is deposited on the roughness recesses 132, but is not deposited on the roughness protrusions 131 almost at all. Thus, as illustrated in FIG. 5B, the material film 30 is formed relatively thick on the roughness recesses 132, and is formed relatively thin on the roughness protrusions 131.

The thickness of the material film 30 is about 1 nm to about 3 nm, for example. The amount of deposition (i.e., thickness) of the material film 30 is controlled by controlling the deposition time, for example.

Next, as illustrated in FIG. 5C, the material film 30 and the compound-containing layer 20 are partially removed. The material film 30 is partially removed by etching using plasma containing a halogen gas added thereto. Examples of a halogen gas include CHF₃, CF₄, and SF₆. Thus, in the step in FIG. 5C, not only the material film 30 but also silicon carbide of the compound-containing layer 20 is etched. It should be noted that FIG. 5C illustrates the timing at which the compound-containing layer 20 on the roughness protrusions 131 is removed and the substrate 10 at the roughness protrusions 131 is partially exposed from the material film 30.

FIG. 5D illustrates a state in which the etching has further proceeded from the state in FIG. 5C. That is, as illustrated in FIGS. 5C and 5D, the material film 30 is partially removed so as to expose the roughness protrusions 131, and also, the compound-containing layer 20 on the roughness protrusions 131 and the substrate 10 at the roughness protrusions 131 are partially removed. Since plasma containing a halogen gas added thereto is used, not only the material film 30 and the compound-containing layer 20 but also the substrate 10 made of quartz is etched. The roughness protrusions 131 illustrated in FIG. 5D have been further etched, and thus have been partially removed and are at a lower level in comparison with the roughness protrusions 131 illustrated in FIGS. 5A to 5C.

The step of removing the material film ends before the material film 30 is entirely removed. Portions of the protrude pattern 11 other than the roughness protrusions 131 remain covered with the material film 30. Thus, the material film 30 serves as a mask, and the substrate 10 and the compound-containing layer 20 other than the roughness protrusions 131 are not removed. Therefore, it is possible to selectively remove the roughness protrusions 131 while leaving the other parts of the uneven pattern 13, and thus improve the line edge roughness.

Next, as illustrated in FIG. 5E, carbon ions are implanted into the uneven pattern 13, and also, the material film 30 is formed so as to cover the uneven pattern 13, so that the compound-containing layer 20 is formed between the substrate at the roughness protrusions 131 and the material film 30. Accordingly, the compound-containing layer 20 partially removed in the step in FIG. 5D can be restored.

Next, as illustrated in FIG. 5F, the material film 30 is removed so as to expose the compound-containing layer 20. The material film 30 is removed by etching using oxygen plasma, for example. As illustrated in FIG. 5F, the level of the roughness protrusions 131 on the side face F13 can be made low, and also, the compound-containing layer 20 can be formed along the uneven pattern 13.

As described above, according to the second embodiment, not only is the material film 30 removed, but also the upper faces of the roughness protrusions 131 are partially removed in the step in FIG. 5D. Accordingly, it is possible to selectively remove the roughness protrusions 131 without adversely affecting the uneven pattern 13. Consequently, selectively removing the roughness protrusions 131 can further reduce the roughness.

The other configurations of the template 1 according to the second embodiment are similar to the corresponding configurations of the template 1 according to the first embodiment. Thus, the detailed description thereof is omitted. The template 1 according to the second embodiment can obtain advantageous effects similar to those in the first embodiment.

### Modified Example of Second Embodiment

In the second embodiment, the step of removing the roughness protrusions 131, which includes the step of depositing the material film 30 (FIG. 5B) and the step of removing the material film 30 (FIGS. 5C and 5D), is performed once. Meanwhile, in a modified example of the second embodiment, the step of removing the roughness protrusions 131 is performed more than once.

Selective removal of the roughness protrusions 131 is possible only while the material film 30 remains, and thus is temporally limited. Herein, if the material film 30 is entirely removed by etching using oxygen plasma and the material film 30 is deposited again, it becomes possible to selectively remove the roughness protrusions 131 again.

If the removal amount of the roughness protrusions 131 per step is increased, controllability may deteriorate. Thus, the removal amount of the roughness protrusions 131 per step is reduced, but the step of removing the roughness protrusions 131 is performed more than once.

First, after the step in FIG. 5D, the material film 30 is entirely removed so as to expose the compound-containing layer 20. The material film 30 is removed by etching using oxygen plasma, for example.

Next, the step of removing the roughness protrusions 131 illustrated in FIGS. 5B to 5D is repeated more than once. That is, as illustrated in FIG. 5B, carbon ions are implanted again, and also, the material film 30 is formed again. Next, as illustrated in FIGS. 5C and 5D, the material film 30 is partially removed again, and also, the compound-containing layer 20 on the roughness protrusions 131 and the substrate 10 at the roughness protrusions 131 are partially removed again.

After that, steps similar to those in and following FIG. 5E of the second embodiment are executed.

### Third Embodiment

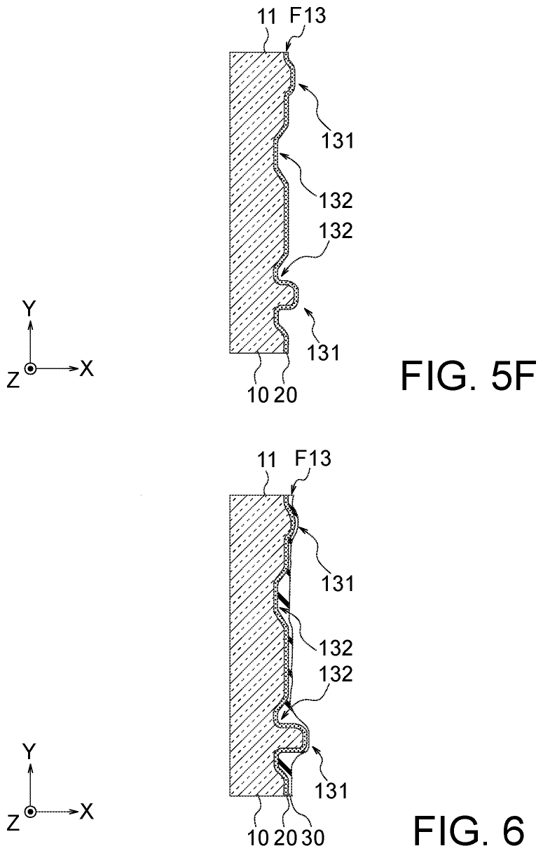

FIG. 6 is a cross-sectional view illustrating an exemplary method of manufacturing the template 1 according to a third embodiment. The third embodiment differs from FIG. 5B in the second embodiment in the thickness of the material film 30 deposited.

First, the uneven pattern 13 is formed on the substrate 10 as in the second embodiment (see FIG. 5A).

Next, as illustrated in FIG. 6, carbon ions are implanted into the uneven pattern 13, and also, the material film 30 is formed so as to cover the uneven pattern 13. More specifically, the material film 30 is formed until at least the roughness recesses 132 are buried. In the example illustrated in FIG. 6, the material film 30 is thinner than that in FIG. 5B of the second embodiment. The material film 30 is not deposited much on and around the roughness protrusions 131 illustrated in FIG. 6. The amount of deposition (i.e., thickness) of the material film 30 is controlled by controlling the deposition time, for example.

After that, steps similar to those in and following FIG. 5C of the second embodiment are executed.

In the third embodiment, it is possible to selectively expose the roughness protrusions 131 even if the removal amount of the material film 30 is reduced.

The other configurations of the template 1 according to the third embodiment are similar to the corresponding configurations of the template 1 according to the second embodiment. Thus, the detailed description thereof is omitted. The template 1 according to the third embodiment can obtain advantageous effects similar to those in the second embodiment. In addition, the template 1 according to the third embodiment may be combined with the modified example of the second embodiment.

### Fourth Embodiment

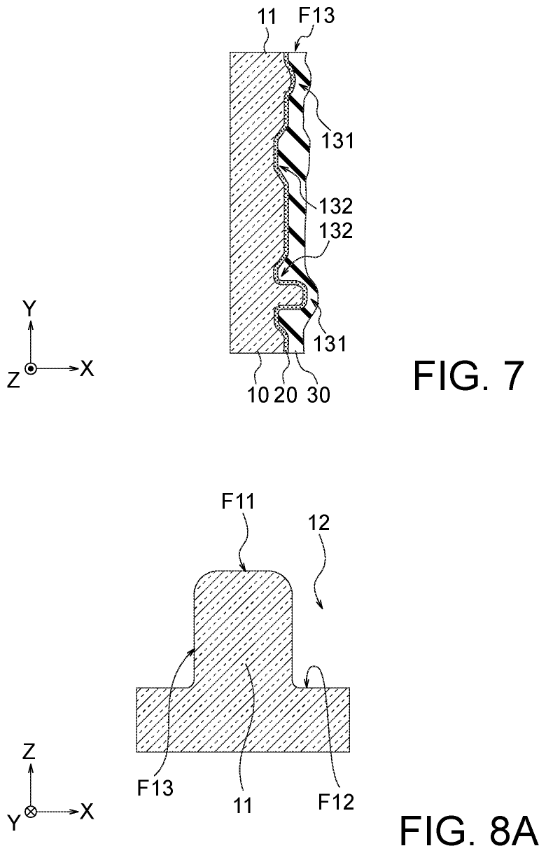

FIG. 7 is a cross-sectional view illustrating an exemplary method of manufacturing the template 1 according to a fourth embodiment. The fourth embodiment differs from FIG. 5B in the second embodiment in the thickness of the material film 30 deposited.

First, the uneven pattern 13 is formed on the substrate 10 as in the second embodiment (see FIG. 5A).

Next, as illustrated in FIG. 7, carbon ions are implanted into the uneven pattern 13, and also, the material film 30 is formed so as to cover the uneven pattern 13. More specifically, the material film 30 is formed until at least the roughness protrusions 131 are buried. In the example illustrated in FIG. 7, the material film 30 is thicker than that in FIG. 5B of the second embodiment. The material film 30 is deposited thick so that the roughness protrusions 131 and their peripheries illustrated in FIG. 7 are sufficiently buried. The amount of deposition (i.e., thickness) of the material film 30 is controlled by controlling the deposition time, for example.

Next, as illustrated in FIGS. 5C and 5D of the second embodiment, the material film 30 is partially removed so as to expose the roughness protrusions 131, and also, the compound-containing layer 20 on the roughness protrusions 131 and the substrate 10 at the roughness protrusions 131 are partially removed. More specifically, the substrate 10 is partially removed at substantially the same etching rate as that of the material film 30.

Herein, the step of removing the material film 30 in the fourth embodiment is performed such that the etch selectivity between the material film 30 and the substrate 10 is substantially 1:1. When the etch selectivity is substantially 1:1, it is possible to etch the substrate 10 together with the material film 30 so as to maintain the surface shape of the material film 30 illustrated in FIG. 7. The material film 30 is the thinnest on the roughness protrusions 131 and their peripheries. Thus, the roughness protrusions 131 are etched the fastest of all regions of the substrate 10. In addition, since the material film 30 is thick on regions other than the roughness protrusions 131, it is possible to suppress etching of the substrate 10 in regions other than the roughness protrusions 131. Thus, the roughness protrusions 131 can be selectively removed more easily.

It should be noted that the etching rate is adjusted by adjusting the gas ratio, for example. The etching rate is adjusted according to the quality of the material film 30, for example.

After that, steps similar to those in and following FIG. 5E of the second embodiment are executed.

The other configurations of the template 1 according to the fourth embodiment are similar to the corresponding configurations of the template 1 according to the second embodiment. Thus, the detailed description thereof is omitted. The template 1 according to the fourth embodiment can obtain advantageous effects similar to those in the second embodiment. In addition, the template 1 according to the fourth embodiment may be combined with the modified example of the second embodiment.

### Fifth Embodiment

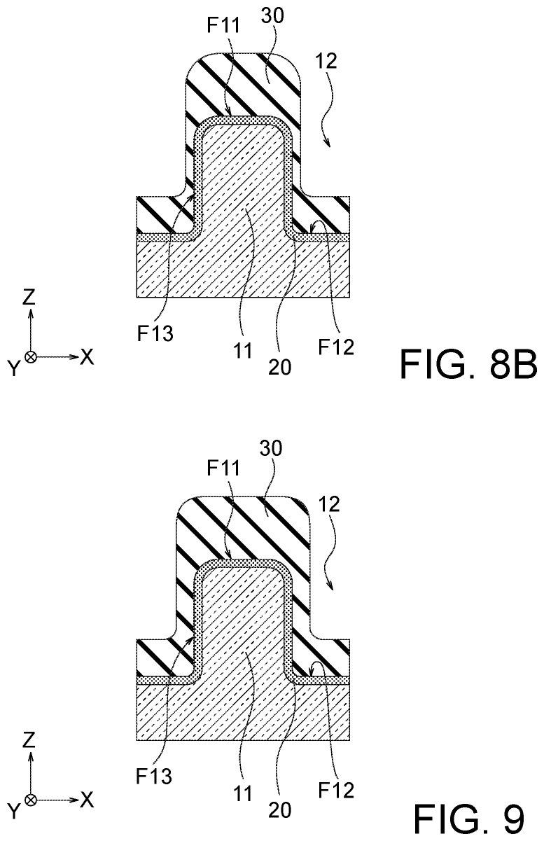

FIGS. 8A and 8B are cross-sectional views illustrating an exemplary method of manufacturing the template 1 according to a fifth embodiment. The fifth embodiment differs from the second embodiment in the method of forming the material film 30.

First, as illustrated in FIG. 8A, the uneven pattern 13 is formed on the substrate 10.

Next, as illustrated in FIG. 8B, carbon ions are implanted into the uneven pattern 13, and also, the material film 30 is formed on the uneven pattern 13. More specifically, the material film 30 is formed such that its deposition rate on the sidewall portion (i.e., the side face F13) of the uneven pattern 13 is lower than its deposition rate on the upper face F11 of the protrude pattern 11 and the bottom face F12 of the recess pattern 12. In the example illustrated in FIG. 8B, the material film 30, which is thinner on the side face F13 than on the upper face F11 and the bottom face F12, is formed.

The way in which the material film 30 deposits on the uneven pattern 13 can be adjusted by adjusting the deposition conditions for the material film 30. To reduce the amount of deposition of the material film 30 on the sidewall portion, it is effective to reduce a radicalized carbon material during deposition of the material film 30. Using FCVA (filtered cathodic vacuum arc) for a plasma source, for example, can efficiently remove radical components.

FIG. 9 is a cross-sectional view illustrating an exemplary method of manufacturing the template 1 according to Comparative Example. In Comparative Example, the material film 30 is formed by PBII&D. Thus, Comparative Example is also the second embodiment.

When FIGS. 8B and 9 are compared, the thickness of each material film 30 deposited on the upper face F11 and the bottom face F12 is substantially the same. Meanwhile, the material film 30 deposited on the side face F13 illustrated in FIG. 8B is thinner than the material film 30 deposited on the side face F13 illustrated in FIG. 9. Thus, in the fifth embodiment, the material film 30 formed on the side face F13 can be made thinner by using FCVA. In FIG. 8B of the fifth embodiment, the amount of deposition of the film on the side face F13 can be reduced by about 30%, for example, in comparison with that in FIG. 9 of Comparative Example. Accordingly, the roughness protrusions 131 on the side face F13 are allowed to be exposed with a smaller removal amount of the material film 30. Meanwhile, the material film on the upper face F11 and the bottom face F12 can be left relatively thick. Accordingly, it is possible to suppress a phenomenon that when the roughness protrusions 131 on the side face F13 are partially removed, the upper face F11 and the bottom face F12 are also partially removed. Thus, the roughness protrusions 131 on the side face F13 can be selectively removed more easily.

The other configurations of the template 1 according to the fifth embodiment are similar to the corresponding configurations of the template 1 according to the second embodiment. Thus, the detailed description thereof is omitted. The template 1 according to the fifth embodiment can obtain advantageous effects similar to those in the second embodiment. In addition, the template 1 according to the fifth embodiment may be combined with the modified example of the second embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A template comprising:
a substrate that includes a first face having a pattern and contains a first element; and
a first layer being in contact with the first face, the first layer containing a compound having the first element and a second element different from the first element, a density of the compound in the first layer being higher than a density of the compound in the substrate.

2. The template according to claim 1, wherein the first layer is a mixed layer of the compound and a material of the substrate.

3. The template according to claim 1,
wherein:
the first element is silicon (Si),
the second element is carbon (C), and
the compound is silicon carbide (SiC).

4. The template according to claim 1,
wherein:
the first element is silicon (Si),
the second element is carbon (C), and
the compound is silicon oxycarbide (SiOC).

5. The template according to claim 1, wherein the substrate is made of quartz.

6. The template according to claim 2, wherein the substrate is made of quartz.

7. A method of manufacturing a template, comprising:
preparing a substrate containing a first element;
implanting ions of a second element different from the first element into at least a pattern of a first face of the substrate forming a material film containing the second element on at least the pattern to form the first layer between the substrate and the material film; and
removing the material film.

8. The method of manufacturing the template according to claim 7, further comprising:
forming the material film such that a deposition rate of the material film on a first protrude portion protruding from a face of the pattern is lower than a deposition rate of the material film on a first recess portion recessed from the face;
partially removing the material film so as to expose the first protrude portion, and partially removing the first layer on the first protrude portion and the substrate at the first protrude portion;
implanting ions of the second element, and forming the material film; and
removing the material film.

9. The method of manufacturing the template according to claim 8, further comprising forming the material film until at least the first recess portion is fully buried.

10. The method of manufacturing the template according to claim 8, further comprising:
forming the material film until at least the first protrude portion is buried, thereby forming the first layer between the substrate and the material film; and
partially removing the material film so as to expose the first protrude portion, and partially removing the first layer on the first protrude portion and the substrate at the first protrude portion at substantially a same etching rate as an etching rate of the material film.

11. The method of manufacturing the template according to claim 8, further comprising:
after partially removing the first layer on the first protrude portion and the substrate at the first protrude portion,
further repeating a process of: removing the material film, forming the material film again, and partially removing the material film again and partially removing the first layer on the first protrude portion and the substrate at the first protrude portion again;
implanting ions of the second element, and forming the material film; and
removing the material film.

12. The method of manufacturing the template according to claim 9, further comprising:
after partially removing the first layer on the first protrude portion and the substrate at the first protrude portion:
further repeating a process of: removing the material film, forming the material film again, and partially removing the material film again and partially removing the first layer on the first protrude portion and the substrate at the first protrude portion again;
implanting ions of the second element, and forming the material film; and
removing the material film.

13. The method of manufacturing the template according to claim 10, further comprising:
after partially removing the first layer on the first protrude portion and the substrate at the first protrude portion, further repeating a process of: removing the material film, forming the material film again, and partially removing the material film again and partially removing the first layer on the first protrude portion and the substrate at the first protrude portion again;
implanting ions of the second element, and forming the material film; and
removing the material film.

14. The method of manufacturing the template according to claim 8, wherein the face is a sidewall portion of the pattern.

15. The method of manufacturing the template according to claim 7,
wherein implanting ions of the second element and forming the material film are performed by using PBII&D (plasma-based ion implantation and deposition).

16. The method of manufacturing the template according to claim 7,
wherein a deposition rate of the material film on a sidewall portion of the pattern is lower than a deposition rate of the material film on an upper face of a second protrude portion and a bottom face of a second recess portion of the pattern.
